(19) United States
(12) Patent Application Publication
(10) Pub. No.: US 2025/0079169 A1
(43) Pub. Date: Mar. 6, 2025

(54) METHODS FOR FORMING SEMICONDUCTOR STRUCTURES INCLUDING TWO-DIMENSIONAL METAL DICHALCOGENIDE LAYERS

(71) Applicant: ASM IP Holding B.V., Almere (NL)

(72) Inventors: Vincent Vandalon, Heverlee (BE); Ren-Jie Chang, Chandler, AZ (US); Giuseppe Alessio Verni, Vantaa (FI); Alessandra Leonhardt, Sipoo (FI); Michael Givens, Oud-Heverlee (BE)

(21) Appl. No.: 18/815,676

(22) Filed: Aug. 26, 2024

Related U.S. Application Data
(60) Provisional application No. 63/535,931, filed on Aug. 31, 2023.

(51) Int. Cl. H01L 21/02

(52) U.S. Cl. CPC H01L 21/02568; H01L 21/02617

(57) ABSTRACT

Methods for forming semiconductor structures including 2D-transition metal dichalcogenide layers, methods for forming gate stacks including metallic 2D-transition metal dichalcogenide layer, as well as methods for forming ternary phase 2D-transition metal dichalcogenide layer by an atomic layer deposition process (ALD) are disclosed.

### CROSS-REFERENCE TO RELATED APPLICATION(S)

This application claims the benefit of U.S. Provisional Application 63/535,931 filed on Aug. 31, 2023, the entire contents of which are incorporated herein by reference.

### FIELD

The present disclosure relates generally to the field of semiconductor processing methods and associated semiconductor structures, and to the field of device and integrated circuit manufacture. More particularly, the present disclosure relates to methods for forming semiconductor structures including 2D-transition metal dichalcogenide layers, and gate stack layers including metallic 2D-transition metal dichalcogenide layers. The present disclosure also relates to methods for forming ternary phase 2D-transition metal dichalcogenide layers and their use in semiconductor device structures.

### BACKGROUND

The scaling of semiconductor devices, such as field-effect-transistors (FETs) and complementary metal-oxide-semiconductor (CMOS) devices, has led to significant improvements in the speed and density of integrated circuits. However, conventional device scaling techniques face significant challenges in future technology nodes. For example, the formation of the gate stack, i.e., the layers of materials between the device channel and the control terminal of the device, faces increasing design restrictions due to the space limitations imposed as device structures move to next-generation architectures, such as, gate-all-around structures, for example. Such design restrictions can impose limitations on the thickness of the layers making up the gate stack. However, certain gate stack layers, such as the layers making up the gate electrode layers, can be negatively impacted by a reduction in layer thickness. Accordingly, methods are desirable that are capable of forming ultra-thin gate stack layer without an associated impact on device performance.

Any discussion, including discussion of problems and solutions, set forth in this section has been included in this disclosure solely for the purpose of providing a context for the present disclosure. Such discussion should not be taken as an admission that any or all of the invention was previously known or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods for forming semiconductor structures, and particularly methods for forming semiconductor structures including 2D-transition metal dichalcogenide layers. As set forth in more detail below, the 2D-transition metal dichalcogenide layers of the present disclosure can be utilized as metallic work function metal layers within the gate stack of a semiconductor device. The 2D-transition metal dichalcogenide layers of the present disclosure allow for ultra-thin gate stacks which are compatible with next generation device architectures. In addition, the 2D-transition metal dichalcogenide layers of the present disclosure can include ternary phase 2D-transition metal dichalcogenide layer (either in an alloy form or in a doped form) which allows for further tuning of the 2D-transition metal dichalcogenide layer properties for optimization to a particular device structure.

In accordance with examples of the disclosure, a method for forming semiconductor structure is provided. In such examples the method can include seating a substrate within a reaction chamber, the substrate including a dielectric layer, and depositing a 2D-transition metal dichalcogenide layer directly on the dielectric layer by performing one or more deposition cycles of a cyclical deposition process. In such examples, each deposition cycle of the cyclical deposition process includes providing a transition metal precursor to the reaction chamber, and providing a chalcogen precursor to the reaction chamber. In such examples, a further step of the methods can include, depositing a metallic capping layer directly on the 2D-transition metal dichalcogenide layer. In some embodiments, the dielectric layer is a high-k dielectric layer. In some embodiments, the cyclical deposition process is an atomic layer deposition process. In some embodiments, the substrate temperature during the atomic layer deposition process is less than 500° C. In accordance with examples of the disclosure, the 2D-transition metal dichalcogenide layer is a metallic work function layer. In such examples, the 2D-transition metal dichalcogenide layer is selected from a group consisting of MoS₂, VS₂, TaS₂, MoTe₂, TaSe₂, NbSe₂, and TiSe₂. In accordance with examples of the disclosure, the chalcogen precursor comprises a chalcogen element selected from a group consisting of sulphur, selenium, and tellurium. In accordance with examples of the disclosure, one or more of the deposition cycles further comprises providing a metal precursor to the reaction chamber. In such examples, the metal precursor is an additional metal element and the transition metal precursor is a transition metal element which is different from the additional metal element. In such examples, the additional metal element is selected from a group consisting of aluminum, tungsten, and tellurium. In such examples, the additional metal element can be a dopant metal element and the 2D-transition metal dichalcogenide layer is a metal doped 2D-transtion metal dichalcogenide layer. In such examples, the additional metal element can be a metal alloying element and the 2D-transition metal dichalcogenide layer is a ternary phase 2D-transtion metal dichalcogenide alloy layer. In accordance with examples of the disclosure, the 2D-transition metal dichalcogenide layer is deposited to a thickness of between 1 nanometer and 5 nanometers. In accordance with examples of the disclosure, the 2D-transition metal dichalcogenide layer is deposited to a thickness between 1 monolayer and 5 monolayers.

Various other embodiments of the present disclosure relate to methods of forming at least a portion of a gate stack for a semiconductor device structure. As set forth in more detail below, the methods described herein can be used to form ultra-thin gate stacks suitable for use in next generation device architecture, such as, for example, gate-all-around (GAA) transistor device structures, nanosheet device structure, and complementary FET (CFET) device structure.

In accordance with examples of the disclosure, methods of forming at least a portion of gate stack for semiconductor device structures are provided. In such examples the methods can include, seating a substrate within a reaction chamber, the substrate including a plurality of partially fabricated device structures, wherein one or more of the partially fabricated device structures include a surface layer comprises a high-k dielectric layer. In such examples, the methods can also include, performing one or more deposition cycles of a first atomic layer deposition process to deposit a metallic 2D-transition metal dichalcogenide work function layer directly on a surface of the high-k dielectric layer, and performing one or more deposition cycles of a second atomic layer deposition process to deposit a metallic capping layer directly on the metallic 2D-transition metal dichalcogenide work function layer. In accordance with examples of the disclosure, the high-k dielectric layer, the metallic 2D-transition metal dichalcogenide work function layer, and the metallic capping layer together comprise a gate stack to the semiconductor device structure. In accordance with examples of the disclosure, the semiconductor device structure can include a NMOS device structure and the effective work function of the gate stack is between 4.2 eV and 4.4 eV with a total gate stack thickness of less than 20 nanometers. In accordance with examples of the disclosure, semiconductor device structure can include a PMOS device structure and the effective work function of the gate stack is between 5.2 eV and 5.6 eV with a total gate stack thickness of less than 20 nanometers.

Various further embodiments of the present disclosure relate to methods for forming ternary phase 2D-transition metal dichalcogenide layers by an atomic layer deposition process, the ternary phase 2D-transition metal dichalcogenide layer having a chemical formula containing a transition metal element, a chalcogen element, and a ternary element comprising a metal element different to the transition metal element. In such examples, a transition metal precursor is used as a source for the transition metal element, a chalcogen precursor is used as the source of the chalcogen element, and a metal precursor is used as the source of the ternary metal element.

These and other embodiments will become readily apparent to those skilled in the art from the following detailed description of certain embodiments having reference to the attached figures. The invention is not limited to any particular embodiments disclosed.

### BRIEF DESCRIPTION OF DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIG. 2 illustrates semiconductor structure in accordance with examples of the disclosure.

FIG. 3 illustrates a further semiconductor structure in accordance with examples of the disclosure.

FIG. 4 illustrates an additional semiconductor structure in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of the exemplary embodiments of the methods provided below are merely exemplary and are intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As set forth in more detail below, various embodiments of the present disclosure relate to methods of forming semiconductor structures including 2D-transition metal dichalcogenide layers. As set forth in more detail, the 2D-transition metal dichalcogenide layers described herein can be used during the manufacture of electronic devices. Such 2D-transition metal dichalcogenide layers can reduce the complexity and/or cost of manufacturing devices/integrated circuits, and increases the functionality of such 2D-transition metal dichalcogenide layers.

In more detail, the continuing down scaling of device structures and related integrated circuits (e.g., FETs, CMOS, etc.) increases the material deposition challenges in not only improving/maintaining materials characteristics whilst at the same time decreasing the material layer thickness. For example, in the case of the layers making up the gate stack to future transistor architectures (e.g., in gate-all-around structures and the like) there will likely be less than 10 nanometers of space available, which can translate into material layer thicknesses of less 5 nanometers for certain layers within the gate stack, such as, for example, the work function metal layers.

To address these issues, the present disclosure provides two-dimensional (2D) materials and particular 2D-transition metal dichalcogenide layer as the work function metals within the gate stack of semiconductor device structure. 2D-materials and particularly 2D-transition metal dichalcogenide layers have been proposed for use within semiconductor device structure previously but such layers have been used as channel regions and/or as phase change materials, and in such cases the 2D-materials have non-metallic and unstable materials properties. In contrast, the present disclosure provides 2D-transition metal dichalcogenide layers having stable metallic properties which can be employed as conductive work function metal layers within the gate stack, as well other functions and uses. The use of 2D-transition metal dichalcogenide layers can alleviate the current stringent space limitations in the gate stack integration due to the inherent atomically-thin thickness of such 2D-materials. Therefore 2D-transition metal dichalcogenide layers can mitigate the requirements for dipole engineering within the gate stack and provide flexibility in the selection of the integration scheme employed (e.g., dipole first, dipole last, dipole patterning, etc.). In addition to the ultra-thin thickness of the 2D-transition metal dichalcogenide layer, the absence of dangling bonds for 2D materials may further assist in the conductivity of the gate stack layers.

The present disclosure also provides ternary phase 2D-transition metal dichalcogenide layers, in either alloyed form or doped form, to further increase the functionality of 2D-materials as stable metallic layers within the gate stack of semiconductor device structures. As a non-limiting example, doped/alloyed 2D-transition metal dichalcogenide layers can be employed as work function metals with tunable electronic properties (such as work function and band gap), such tunable properties being controlled at least in part by the choice of materials, precursors, deposition process, and alloying/doping elements within the ternary phase metallic 2D-transition metal dichalcogenide layer.

As used herein, the terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. In some cases, the term reactant can be used interchangeably with the term precursor.

As used herein, the term “transition metal precursor” can refer to a precursor that can be represented by a chemical formula that includes a transition metal element.

As used herein, the term “chalcogen precursor” can refer to a precursor that can be represented by a chemical formula that includes a chalcogen element, wherein a chalcogen is an element from Group VI of the periodic table including sulphur, selenium, and tellurium.

As used herein, the terms “metallic” and “metallic layer” can refer to materials and material layers with metallic properties and/or semimetallic properties.

As used herein, the terms “stable” and “stable layer” can refer to materials and material layers with properties which are substantially unchanging when under voltage biasing conditions and operation.

As used herein, the term “layer” and “film” can refer to any continuous or non-continuous structure and material, such as material formed and/or deposited by the methods disclosed herein. For example, a layer (or film) can include two-dimensional materials, three-dimensional materials, nanoparticles or even partial or full molecular layers or partial or full atomic layers or clusters of atoms and/or molecules. A layer may comprise material or a layer with pinholes. A layer may be at least partially continuous. A layer may be patterned, e.g., subdivided, and may be comprised of a plurality of semiconductor devices.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group Ill-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

As used herein, the term “structure” and “semiconductor structure” can be or include a substrate as described herein. Structures can include a substrate and one or more layers overlying the substrate, such as one or more layers formed by a method according to the current disclosure. The structure may include or be used in the formation of, for example, a via or a line in BEOL processing, or a contact or a local interconnect in MEOL processing. The structure may also be used to form a layer in a gate stack, a gate electrode, a buried power rail in logic applications, as well as a word line or a bit line in an advanced memory application. A “structure” can also include fabricated and/or partially fabricated device structures, such as, transistor, memory, and/or logic elements.

As used herein, the term “cyclical deposition” can refer to the sequential introduction of precursors (also called reactants) into a reaction chamber to deposit a layer (or film) over a substrate and includes deposition techniques such as atomic layer deposition, cyclical chemical vapor deposition, plasma-enhanced atomic layer deposition, and plasma-enhanced cyclical chemical vapor deposition.

As used herein, the term “atomic layer deposition” (ALD) can refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “cyclical chemical vapor deposition” can refer to any process wherein a substrate is sequentially exposed to two or more volatile precursors, which react and/or decompose on a substrate to produce a desired deposition.

As used herein, the term “purge” can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be effected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

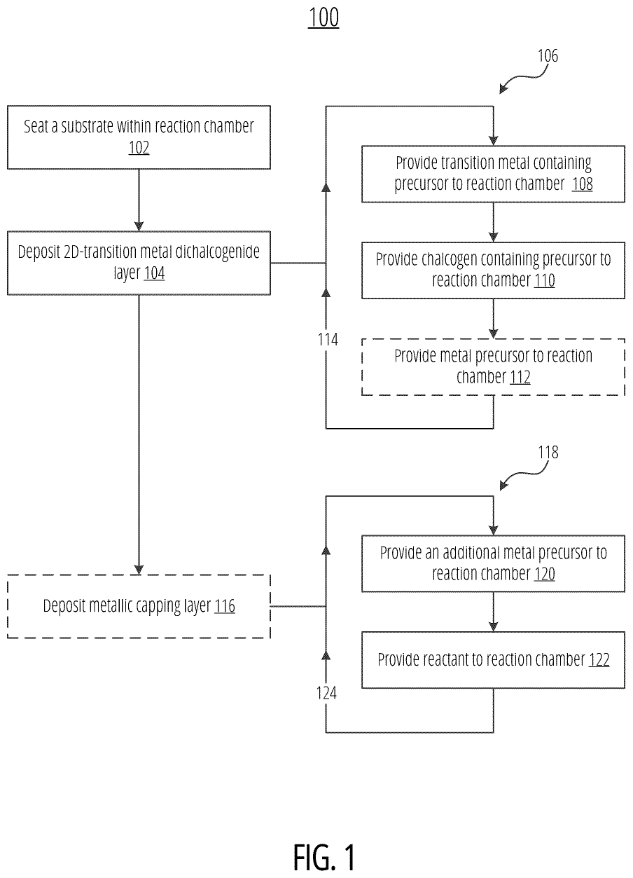

Turning now to the figures, FIG. 1 illustrates an exemplary method 100. Method 100 includes the steps of seating a substrate within a reaction chamber (step 102), depositing a 2D-transition metal dichalcogenide layer on the substrate (step 104), and optionally depositing a metallic capping layer on the 2D-transition metal dichalcogenide layer (step 116).

During step 102, a substrate is seated within a reaction chamber. The reaction chamber used during step 102 can be or include a reaction chamber of a chemical vapor deposition reactor system configured to perform a chemical vapor deposition process or a cyclical deposition process. In some embodiments, the reaction chamber used during step 102 can be or include a reaction chamber of an atomic layer deposition reactor system configured to perform a cyclical deposition process. In some embodiments, the reaction chamber used during step 102 can be or include a reaction chamber of a plasma-enhanced atomic layer deposition reactor system configured to perform a cyclical deposition process employing suitable plasma species. In some embodiments, the reaction chamber used during step 102 can be or include a reaction chamber of a plasma-enhanced chemical vapor deposition reactor system configured to perform a cyclical deposition process employing suitable plasma species.

The reaction chamber can be a standalone reaction chamber or part of a cluster tool. The reaction chamber can include a substrate heater to heat a substrate to a substrate temperature noted herein.

In accordance with examples of the disclosure, the substrate seated within the reaction chamber during step 102 can include a dielectric layer. In such examples, the dielectric layer is a surface dielectric layer. In some embodiments, the dielectric layer comprises a high dielectric constant layer (i.e., a high-k dielectric layer), where the high-k dielectric layer demonstrating a dielectric constant greater than about 7. Exemplary high-k dielectric layers include, but are not limited to, hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃), lanthanum oxide (La₂O₃), and mixtures/laminates comprising one or more such layers.

In accordance with examples of the disclosure, the dielectric layer may comprise a portion of a partially fabricated device structure and/or integrated circuit structure. In such examples, one or more of the partially fabricated device structures can include a surface layer comprising a high-k dielectric layer. In such examples, the high-k dielectric layer can be selected from a group of materials consisting of HfO₂, Ta₂O₅, ZrO₂, TiO₂, HfSiOₓ, Al₂O₃, La₂O₃, and mixtures/laminates comprising one or more such layers. In accordance with examples of the disclosure, the high-k dielectric layer can comprise a portion of a gate stack of a partially fabricated semiconductor device structure.

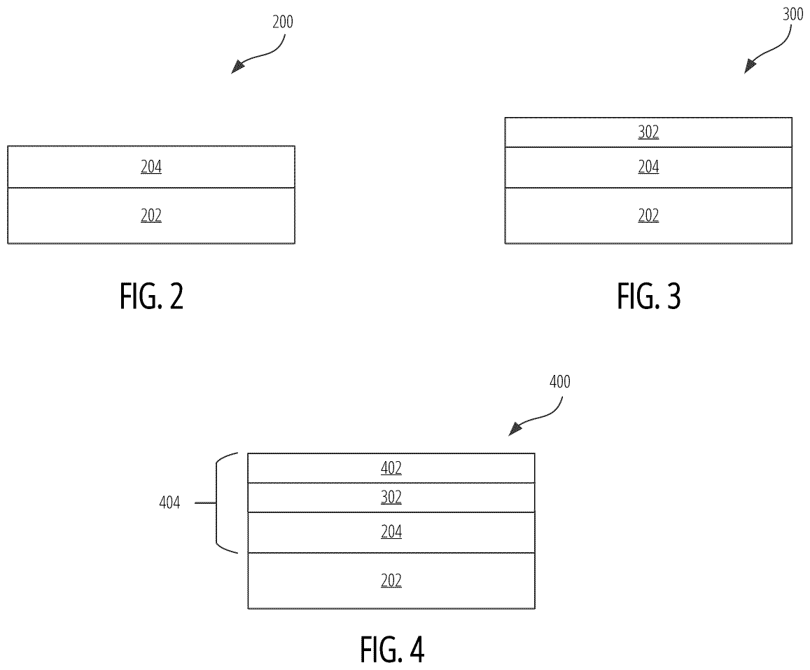

FIG. 2 illustrates a portion of a substrate suitable for use as a substrate during step 102. Substrate 200 includes a semiconductor body 202 and a dielectric layer 204 disposed on the semiconductor body. The dielectric layer 204 can further include an interface layer disposed between the semiconductor body 202 and the dielectric layer 204 (not shown). In accordance with examples of the disclosure, the substrate 200 can form part of a partially fabricated semiconductor device structure, such as, a gate-all-around transistor, a nanosheet transistor, a forksheet transistor, a complementary FET (CFET) device, a CMOS device structure, and/or a memory device (e.g., DRAM). In such examples, the dielectric layer 204 can comprise a high-k dielectric layer and can form a portion of a gate stack. In such examples, the underlying region of the semiconductor body 202 adjacent to the dielectric layer 204 can include a channel region of a semiconductor device structure.

Once the substrate is seated within the reaction chamber (step 102), the method 100 can continue with the step of depositing a 2D-transition metal dichalcogenide layer on a surface of the substrate (step 104). In accordance with examples of the disclosure, step 104 includes depositing a 2D-transition metal dichalcogenide layer directly on the dielectric layer disposed on the surface of the substrate, i.e., directly on dielectric layer 204 of FIG. 2.

The step of depositing the 2D-transition metal dichalcogenide layer (step 104) can be performed at a substrate temperature between 100° C. and 500° C., or between 150° C. and 400° C., or between 250° C. and 350° C., or between 275° C. and 325° C., or between 280° C. and 320° C. In some embodiments, the step of depositing the 2D-transition metal dichalcogenide layer (step 104) can be performed at a substrate temperature of less than 500° C., or less than 400° C., or less than 300° C., or less than 200° C., or less than 100° C. In alternative embodiments of the disclosure, the 2D-transition metal dichalcogenide layer may be deposited on a surface of substrate not including a sensitive dielectric layer, and in such embodiments the thermal budget of the deposition step 104 may be increased. In such examples, the step of depositing the 2D-transition metal dichalcogenide layer (step 104) can be performed at a substrate temperature between 100° C. and 800° C., or between 200° C. and 700° C., or between 300° C. and 400° C. In such examples, the step of depositing the 2D-transition metal dichalcogenide layer (step 104) can be performed at a substrate temperature of less than 800° C., or less than 600° C., or less than 500° C., or less than 450° C., or less than 400° C.

In addition to controlling the temperature of the substrate, a pressure within the reaction chamber can also be regulated. For example, in some embodiments of the disclosure, the pressure within the reaction chamber during step 102 may be less than 760 Torr or between 0.2 Torr and 760 Torr, about 1 Torr and 100 Torr, or about 1 Torr and 10 Torr.

In accordance with examples of the disclosure, the step of depositing the 2D-transition metal dichalcogenide layer (step 104) can comprise a cyclical chemical vapor deposition process.

In accordance with further examples of the disclosure, the step of depositing the 2D-transition metal dichalcogenide layer on a surface of the dielectric layer (step 104) can include a thermal deposition process, such as thermal cyclical deposition process. In thermal deposition processes, the chemical reactions are promoted by increased temperature relevant to ambient temperature. In alternative embodiments, the step of depositing the 2D-transition metal dichalcogenide layer on a surface of the dielectric layer (step 104) can include a plasma assisted deposition process, such as plasma-enhanced atomic layer deposition, or plasma-enhanced cyclical chemical vapor deposition. In such plasma assisted deposition processes, the chemical reactions are promoted by suitable plasma precursors/reactants.

In accordance with further examples of the disclosure, and referring to FIG. 1, the step of depositing the 2D-transition metal dichalcogenide layer (step 104) can comprise a thermal cyclical deposition process. In such examples, the step of depositing a 2D-transition metal dichalcogenide layer (step 104) directly on a dielectric layer can comprise an cyclical deposition process 106, such as an atomic layer deposition process. In accordance with examples of the disclosure, the cyclical deposition process 106 can include providing a transition metal precursor to the reaction chamber to form an absorbed transition metal species on the surface of dielectric layer (step 108), and providing a chalcogen precursor to the reaction chamber (step 110) to react with the transition metal species to form the 2D-transition metal dichalcogenide layer directly on the surface of the dielectric layer. In some examples of the disclosure, an optional step of the cyclical deposition process 106 includes providing a metal precursor to the reaction chamber (step 112) to form a ternary phase 2D-transition metal dichalcogenide layer, this option will be described in greater detail below.

In accordance with examples of the disclosure, steps 108 and 110 (and optional step 112) can be repeated as illustrated by loop 114, each loop comprising an individual deposition cycle of the cyclical deposition process 106, such as an atomic layer deposition process. Further, steps 108 and 110 (and optional step 112) can be initiated and/or terminated in any order. Yet further, cyclical deposition process 106 can include one or more (e.g., 1-3, or 1-5, or 1-10) repetitions of steps 108 and/or 110 (and/or optional step 112) prior to proceeding to the next process step of the cyclical deposition process 106.

In accordance with examples of the disclosure, during step 108, a transition metal precursor is provided to the reaction chamber. The temperature and pressure within the reaction chamber can be as described above in connection with step 104.

In some embodiments, the transition metal precursor is provided as a single compound or as a mixture of two or more compounds. In a mixture, the other compound(s) in addition to the transition metal compound may be one or more inert compounds or elements—i.e., inert gases. In some embodiments, the transition metal precursor is provided in a composition. Compositions suitable for use can include a transition metal compound and an effective amount of one or more stabilizing agents and/or inert or carrier gases, such as argon, nitrogen, and/or hydrogen. Compositions may be a solution or a gas at NTP.

In accordance with examples of the disclosure, the transition metal precursor comprises a transition metal element. In such example, the transition metal precursor comprises a chemical formula including at least one transition metal element. In such examples, the transition metal element can be selected from a group consisting of molybdenum, vanadium, tantalum, niobium, and titanium. Further in such examples, the transition metal precursor can include a vapor phase transition metal halide.

In accordance with examples of the disclosure, the transition metal precursor can comprise a molybdenum precursor. In such examples, the molybdenum precursor can comprise a molybdenum halide precursor. In further examples, the molybdenum halide precursor can comprise a molybdenum chalcogenide and in some embodiments the molybdenum halide precursor can comprise a molybdenum chalcogenide halide. For example, the molybdenum chalcogenide halide precursor can include a molybdenum oxyhalide selected from a group consisting of a molybdenum oxychloride, a molybdenum oxyiodide, and a molybdenum oxybromide. In example embodiments, the molybdenum halide precursor can comprise a molybdenum oxychloride, including, but not limited to, molybdenum (V) trichloride oxide (MoOC₃), molybdenum (VI) tetrachloride oxide (MoOCl₄), and molybdenum (IV) dichloride dioxide (MoO₂Cl₂). In some embodiments, the molybdenum precursor comprises a cyclopentadienyl (Cp) ligand. For example, the molybdenum precursor may comprise, consist essentially of, or consist of MoCp₂Cl₂ or MoCp₂H₂, Mo(iPrCp)₂Cl₂, Mo(iPrCp)₂H₂, Mo(EtCp)₂H₂. As non-limiting examples, the molybdenum precursor can also comprise at least one of: molybdenum pentachloride (MoCl₅), molybdenum hexachloride (MoCl), molybdenum hexafluoride (MoF), molybdenum triiodide (Mol₃), or molybdenum dibromide (MoBr₂).

In accordance with further examples of the disclosure, the transition metal precursor can comprise a vanadium precursor. In such examples, the vanadium precursor can be selected from a group consisting of a vanadium halide, a vanadium oxyhalide, and an organometallic vanadium compound. In some embodiments, the vanadium precursor can comprise a vanadium halide. In some embodiments, the vanadium halide comprises vanadium chloride. In some embodiments, the vanadium chloride comprises vanadium(IV) chloride. In some embodiments, the vanadium precursor comprises a vanadium beta-diketonate.

In accordance with further examples of the disclosure, the transition metal precursor can comprise a tantalum precursor. In such examples, the tantalum precursor can comprise one or more alkylamine ligands. Suitable tantalum precursors can include pentakis(dimethylamino)tantalum(V). In some embodiments, the tantalum precursor can be selected from a group consisting of pentakis(dimethylamino)tantalum, tantalum(V)ethoxide, tris(diethylamido)(tert-butylimido)tantalum, tris(ethylmethylamido)(tert-butylimido) tantalum, tantalum tetraethoxy dimethylaminoethoxide, and tert-butylimidotris(diethylamido) tantalum.

In accordance with further examples of the disclosure, the transition metal precursor can comprise a niobium precursor. In such examples, the niobium precursor can be selected from a group consisting of (tert-butylimido)-tris-(diethylamino)-niobium (Nb(NtBu)(NEt₂)₃), Nb(OEt)₅, NbF₅, NbCl₅, and NbF₅.

In accordance with further examples of the disclosure, the transition metal precursor can comprise a titanium precursor. In such examples, the titanium precursor can be selected from a group consisting of titanium tetrachloride (TiCl₄), titanium tetraiodide (Til₄), titanium tetrabromide (TiBr₄), Ti(NEt₂)₄, Ti(NEtMe)₃(guan-NEtMe), Ti(NMe₂)₄, Ti(NMeEt)₄, Ti(OEt)₄, Ti(OⁱPr)₂(dmae)₂, Ti(OⁱPr)₂(thd)₂, and Ti(OiPr).

The duration of step 108 (FIG. 1) during each deposition cycle of cyclical deposition process 106 can be between 0.1 seconds and 60 seconds, between 0.1 seconds and 10 seconds, or between 0.5 seconds and 5.0 seconds. The flow rate of the transition metal precursor to the reaction chamber can be less than 1000 sccm, or less than 500 sccm, or less than 100 sccm, or less than 10 sccm, or less than 1 sccm, or range from 1 sccm to 2000 sccm, from 5 sccm to 1000 sccm, or from 10 sccm to 500 sccm.

During step 110, a chalcogen precursor is provided to the reaction chamber. In such examples, the chalcogen precursor can comprise at least one chalcogen element selected from group VI of the periodic table. In accordance with examples of the disclosure, the chalcogen precursor comprises at least one chalcogen element selected from a group consisting of sulphur, selenium, and tellurium.

In accordance with examples of the disclosure, the chalcogen precursor can be selected from a group consisting of hydrogen sulfide (H₂S), hydrogen selenide (H₂Se), dimethyl sulfide ((CH₃)₂S), and dimethyl telluride (CH₃)₂Te. In some embodiments, the chalcogen precursor is selected from the following list: H₂S, H₂Se, H₂Te, (CH₃)₂S, (NH₄)₂S, dimethylsulfoxide ((CH₃)₂SO), (CH₃)₂Se, (CH₃)₂Te, elemental or atomic S, Se, Te, other precursors containing chalcogen-hydrogen bonds, such as H₂S₂, H₂¬Se₂, H₂Te₂, or chalcogenols with the formula R—Y—H, wherein R can be a substituted or unsubstituted hydrocarbon, preferably a C1-C8 alkyl or substituted alkyl, such as an alkylsilyl group, more preferably a linear or branched C1-C5 alkyl group, and Y can be S, Se, orTe. In some embodiments the chalcogen precursor is a thiol with the formula R—S—H, wherein R can be substituted or unsubstituted hydrocarbon, preferably C1-C8 alkyl group, more linear or branched preferably C₁-C₅ alkyl group. In some embodiments the chalcogen precursor has the formula (R₃Si)₂Y, wherein R₃Si is an alkylsilyl group and Y can be Se or Te. In some embodiments, a chalcogen precursor comprises S or Se. In some embodiments, a chalcogen precursor comprises S. In some embodiments the chalcogen precursor may comprise an elemental chalcogen, such as elemental sulfur. In some embodiments, a chalcogen precursor does not comprise Te. In some embodiments, a chalcogen precursor does comprise Se. In some embodiments, a chalcogen precursor is selected from precursors comprising S, Se or Te.

In some embodiments the chalcogen precursor may comprise a chalcogen plasma, chalcogen atoms or chalcogen radicals. In some embodiments where an energized chalcogen precursor is desired, a plasma may be generated in the reaction chamber or upstream of the reaction chamber. In some embodiments the chalcogen precursor does not comprise an energized chalcogen precursor, such as plasma, atoms or radicals. In some embodiments the chalcogen precursor may comprise a chalcogen plasma, chalcogen atoms or chalcogen radicals formed from a chalcogen precursor comprising a chalcogen-hydrogen bond, such as H₂S. In some embodiments a chalcogen precursor may comprise a chalcogen plasma, chalcogen atoms or chalcogen radicals such as a plasma comprising sulfur, selenium or tellurium, preferably a plasma comprising sulfur. In some embodiments, the plasma, atoms, or radicals comprise tellurium. In some embodiments, the plasma, atoms or radicals comprise selenium. In some embodiments the chalcogen precursor does not comprise a tellurium precursor.

During step 110 of method 100 (FIG. 1), the flow rate of the chalcogen precursor to the reaction chamber can be greater than zero and less than 250 sccm, or less than 200 sccm, or less than 150 sccm, or less than 100 sccm, or less than 50 sccm, or less than 25 sccm, or less than 15 sccm, or less than 10 sccm. In such examples, the flow rate of the chalcogen precursor to the reaction chamber can be between 10 sccm and 250 sccm, or between 15 sccm and 200 sccm, or between 25 sccm and 150 sccm. In some embodiments, the chalcogen precursor is provided to the reaction chamber for a time period of between 0.1 seconds and 2.0 seconds, or between 0.01 seconds and 10 seconds, or less than 20 seconds, or less than 10 seconds, or less than 5 seconds.

The cyclical deposition process 106 can be repeated until an end criteria is met. For example, the end criteria can be based on the number of deposition cycles performed, or by the desired thickness of the 2D-transition metal dichalcogenide layer deposited. In accordance with examples of the disclosure, the 2D-transition metal dichalcogenide layer can be deposited to an average layer thickness of between 1 nanometers and 10 nanometers, or between 2 nanometers and 6 nanometers or between 3 nanometers and 5 nanometers. In some embodiments, the 2D-transition metal dichalcogenide layer is deposited to an average layer thickness of greater than 0 nanometers and less than 10 nanometers, or less than 8 nanometers, or less than 6 nanometer, or less 5 nanometers, or less than 4 nanometers, or less than 3 nanometers, or less than 2 nanometers, or less than 1 nanometer, or between 1 nanometer and 5 nanometers. In accordance with examples of the disclosure, the 2D-transition metal dichalcogenide layer can be deposited to have a thickness of between 1 monolayer and 6 monolayers, or between 2 monolayers and 5 monolayers, or between 3 monolayers and 4 monolayers. In such examples, the 2D-transition metal dichalcogenide layer can be deposited to have a thickness of less than 6 monolayers, or less than 5 monolayers, or less than 4 monolayers, or less than 3 monolayers, or less than 2 monolayers, or equal to 1 monolayer.

In accordance with examples of the disclosure, each deposition cycle of the cyclical deposition process 106 can comprise providing a transition metal precursor to the reaction chamber (step 108), and providing a chalcogen precursor to the reaction chamber (step 110), with the omission of the optional step 112. In such examples, the cyclical deposition process 106 deposits a binary phase 2D-transition metal dichalcogenide layer directly on the dielectric layer. In such examples, the deposited 2D-transition metal dichalcogenide layer can be selected from a group consisting of MoS₂, VS₂, TaS₂, MoTe₂, TaSe₂, NbSe₂, TiSe₂. In some embodiments, the binary phase 2D-transition metal dichalcogenide layer deposited by the methods of the disclosure have the general formula AXC_{y} where A is a transition metal element, C is chalcogen element, and X and Y denote the composition of the binary phase 2D-transition metal dichalcogenide layer.

In accordance with further examples of the disclosure, each deposition cycle of the cyclical deposition process 106 can comprise, providing a transition metal precursor to the reaction chamber (step 108), providing a chalcogen precursor to the reaction chamber (step 110), wherein one or more of the deposition cycles further includes, providing a metal precursor to the reaction chamber (step 112). In some embodiments, each of the deposition cycles includes providing the metal precursor to the reaction chamber (step 112), such the each deposition cycle of the cyclical deposition process 106 comprises, providing a transition metal precursor to the reaction chamber (step 108), providing a chalcogen precursor to the reaction chamber (step 110), and providing a metal precursor to the reaction chamber (step 112).

In other embodiments, the optional step of providing the metal precursor may be performed once every 2 deposition cycles, or once every 3 deposition cycles, or once every 4 deposition cycles, or once every 5 deposition cycles, or once every 6 deposition cycles, or once every 7 deposition cycles, or once every 8 deposition cycles, or once every 9 deposition cycles, or once every 10 deposition cycles.

In other embodiments of the disclosure, the metal precursor can be provided to the reaction chamber (step 112), along with the transition metal precursor (step 108), or along with the chalcogen precursor (step 110). In such cases, step 112 may have at least some temporal overlap with step 108 and/or step 110.

In accordance with examples of the disclosure, the addition of the optional step 112 comprising providing a metal precursor to the cyclical deposition process 106 can be used to deposit a ternary phase 2D-transition metal dichalcogenide layer. In such examples, the ternary phase 2D-transition metal dichalcogenide layer can be an alloyed 2D-transition metal dichalcogenide layer or a doped 2D-transition metal dichalcogenide layer. In such examples, the metal precursor provides an additional metal element to deposit an alloyed 2D-transition metal dichalcogenide layer or provides an additional metal element to deposit a doped 2D-transition metal dichalcogenide layer. In such examples, the metal precursor comprises an additional metal element which is selected to be different from the transition metal element provided by the transition metal precursor in step 108. In such examples, the metal precursor contains an additional metal element and the transition metal precursor contains a transition metal element which is different to additional metal element. In some embodiments, the metal precursor comprises a dopant metal element and the deposited layer comprises a ternary phase doped 2D-transition metal dichalcogenide layer. Alternatively, in some embodiments, the metal precursor comprises an alloying metal element and the deposited layer comprises a ternary phase alloyed 2D-transition metal dichalcogenide layer.

In accordance with examples of the disclosure, the additional metal element provided by the metal precursor during optional step 112 is selected from a group consisting of group 6 metals, group 13 metals, and group 16 metals. In some embodiments, the additional metal element provided by the metal precursor during optional step 112 is selected from a group consisting of aluminum, tungsten, and tellurium. In some embodiments, the additional metal element provided by the metal precursor during optional step 112 is selected from group 6 metals. In some embodiments, the additional metal element provided by the metal precursor during optional step 112 is aluminum. In such examples, the cyclical deposition process 106 deposits a ternary phase 2D-transition metal dichalcogenide layer directly on the dielectric layer.

In accordance with examples of the disclosure, the deposited ternary 2D-transition metal dichalcogenide layer is a ternary alloy selected from a group of 2D-transition metal dichalcogenide alloy layers consisting of MoAlₓS_{y}, MoWₓS_{y}, MoTeₓS_{y}, VAlₓS_{y}, VWₓS_{y}, VTeₓS_{y}, TaAlₓS_{y}, TaWₓS_{y}, TaTeₓS_{y}, MoAlₓTe_{y}, MoWₓTe_{y}, TaAlₓSe_{y}, TaWₓSe_{y}, TaTeₓSe_{y}, NbAlₓSe_{y}, NbWₓSe_{y}, NbTeₓSe_{y}, TiAlₓSe_{y}, TiWₓSe_{y}, and TiTeₓSe_{y}. In some embodiments, the deposited ternary 2D-transition metal dichalcogenide layer comprises an alloy having the general formula AₓB_{y}C_{z} where A is a transition metal element, B is a metal element different to the transition metal element A, C is a chalcogen element, and X, Y and Z denote the composition of the alloy layer.

In accordance with further examples of the disclosure, the deposited ternary 2D-transition metal dichalcogenide layer is a doped 2D-transition metal dichalcogenide layer selected from a group of doped 2D-transition metal dichalcogenide layers consisting of Al:MoₓS_{y}, W:MoₓS_{y}, Te:MoₓS_{y}, Al:VₓS_{y}, W:VₓS_{y}, Te:VₓS_{y}, Al:TaₓS_{y}, W:TaₓS_{y}, Te:TaₓS_{y}, Al:MoₓTe_{y}, W:MoₓTe_{y}, Al:TaₓSe_{y}, W:TaₓSe_{y}, Te:TaₓSe_{y}, Al:NbₓSe_{y}, W:NbₓSe_{y}, Te:NbₓSe_{y}, Al:TiₓSe_{y}, W:TiₓSe_{y}, and Te:TiₓSe_{y}. In some embodiments, the deposited doped 2D-transition metal dichalcogenide layer comprises a doped 2D-transition metal dichalcogenide layer having the general formula B:AₓC_{y} where B is the doping metal element, A is a transition metal element different from the doping metal element B, C is a chalcogen element, and X and Y denote the composition of the doped layer.

FIG. 3 illustrates a structure 300 after the completion of the deposition of the 2D-transition metal dichalcogenide layer (step 104). As illustrated, a 2D-transition metal dichalcogenide layer 302 is deposited directly on the dielectric layer 204. In such examples, the 2D-transition metal dichalcogenide layer 302 is deposited directly on the dielectric layer 204 (e.g., a high-k dielectric layer) without any intervening layer(s) between the 2D-transition metal dichalcogenide layer 302 and the dielectric layer 204.

In accordance with examples of the disclosure, the 2D-transition metal dichalcogenide layer 302 is a work function metal layer. In some embodiments of the disclosure, the 2D-transition metal dichalcogenide layer 302 is a metallic layer having stable metallic properties, such that the 2D-transition metal dichalcogenide layer 302 maintains its metallic properties under biasing conditions when employed within a functioning semiconductor device structure. In accordance with examples of the disclosure, the 2D-transition metal dichalcogenide layers of the present disclosure have stable work function properties. In accordance with examples of the disclosure, the 2D-transition metal dichalcogenide layers of the present disclosure have stable conductivities/resistivities. In accordance with examples of the disclosure, the 2D-transition metal dichalcogenide layers of the present disclosure have stable band-gap energies. In some embodiments of the disclosure, the 2D-transition metal dichalcogenide layer 302 is not a phase change material. In addition, in some embodiments of the disclosure, the 2D-transition metal dichalcogenide layer 302 is not a channel material.

Method 100 (FIG. 1) can continue with an optional step of depositing a metallic capping layer on the 2D-transition metal dichalcogenide layer. In some embodiments, a metallic capping layer is deposited directly on the 2D-transition metal dichalcogenide layer. In accordance with examples of the disclosure, the 2D-transition metal dichalcogenide layer can function as a metallic work function layer, and the optional metallic capping layer can function as a conductive electrode to complete the gate stack. In such examples, the dielectric layer (e.g., the high-k dielectric layer) on the surface of the substrate functions as the gate dielectric layer (either with or without an intervening interface layer between a channel region and the gate dielectric layer), the 2D-transition metal dichalcogenide layer functions as the work function metal layer, and the metallic capping layer functions as the gate electrode layer.

In accordance with examples of the disclosure, optional step 116 comprises depositing a metallic capping layer on the 2D-transition metal dichalcogenide layer. In such examples, the metallic capping layer can be deposited by a further cyclical deposition process 118. In such examples, the 2D-transition metal dichalcogenide layer can be deposited by performing one or more deposition cycles of a first cyclical deposition process 106, as described above, and the metallic capping layer can be deposited by performing one or more deposition cycles of a second cyclical deposition process 118. In accordance with examples of the disclosure, the 2D-transition metal dichalcogenide layer can be deposited by performing one or more deposition cycles of a first atomic layer deposition process to deposit a metallic 2D-transition metal dichalcogenide work function layer directly on a surface of a high-k dielectric layer, as described above with reference to cyclical deposition process 106. In such examples, the metallic capping layer can be deposited by performing one or more deposition cycles of a second atomic layer deposition process to deposit a metallic capping layer directly on the metallic 2D-transition metal dichalcogenide layer (cyclical deposition process 118). In some embodiments, the optional metallic capping is deposited directly on the 2D-transition metal dichalcogenide layer within the same reaction chamber, without any intervening layers being disposed between the 2D-transition metal dichalcogenide layer and the metallic capping layer, and without breaking vacuum between deposition processes.

In accordance with examples of the disclosure, each deposition cycle of the second cyclical deposition process 118 (e.g., the second atomic deposition process) can comprise, providing an additional metal precursor to the reaction chamber (step 120), and providing a reactant to the reaction chamber (step 122). In accordance with examples of the disclosure, the optional metallic capping layer can be or include one or more of titanium nitride; vanadium nitride; a metal stack including titanium nitride and a metal (e.g., W, Co, Ru, Mo) or titanium nitride, titanium aluminum carbon, and titanium nitride; tungsten; tungsten carbon nitride; cobalt; copper; molybdenum; ruthenium; or the like. In such examples, the additional metal precursor provided to the reaction chamber during step 120 can include a metal element selected from a group consisting of Ti, Va, W, Co, Ru, Mo, Cu, and Mo. In addition, in such examples, the reactant provide to the reaction chamber during step 122 can be selected from a group consisting of reducing agents, nitriding agent, carbonizing agents, and/or mixtures and combinations thereof.

In accordance with examples of the disclosure, steps 120 and 122 can be repeated as illustrated by loop 124 (FIG. 1), each loop comprising an individual deposition cycle of the cyclical deposition process 118, such as a second atomic layer deposition process. Further, steps 120 and 122 can be initiated and/or terminated in any order. Yet further, cyclical deposition process 118 can include one or more (e.g., 1-3, or 1-5, or 1-10) repetitions of steps 120 and/or 122 prior to proceeding to the next process step of the cyclical deposition process 118.

The cyclical deposition process 118, e.g., the second atomic layer deposition process, can be repeated until an end criteria are met. For example, the end criteria can be based on a number of deposition cycles performed, or by the desired thickness of the metallic capping layer deposited. The metallic capping should be closed, and in accordance with examples of the disclosure, the metallic capping can be deposited to an average layer thickness of at least about 0.5 nanometer, such as 1 nanometer, or 1.5 nanometer or 3 nm. In accordance with other examples of the disclosure, the metallic capping can be deposited to an average layer thickness of less than 20 nanometer, or less than 15 nanometer, or less than 10 nanometer, or less than 5 nanometer, or less than 3 nanometer.

FIG. 4 illustrates a structure 400 after the completion of the deposition of the optional metallic capping layer (step 116). As illustrated, the metallic capping layer 402 is deposited on the 2D-transition metal dichalcogenide layer 302. In such examples, the metallic capping layer 402 can be deposited directly on the 2D-transition metal dichalcogenide layer 302. In such examples, the 2D-transition metal dichalcogenide layer 302 can be disposed directly between the metallic capping layer 402 and the dielectric layer 204, e.g., the high-k dielectric layer. In some embodiments, the metallic capping 402 can be deposited directly on the 2D-transition metal dichalcogenide layer 302 without any intervening layer(s) between the metallic capping layer 402 and the 2D-transition metal dichalcogenide layer 302.

In accordance with examples of the disclosure, structure 400 (of FIG. 4) includes a gate stack 404 (or at least a portion of a gate stack). In such examples, the dielectric layer 204 (e.g., the high-k dielectric layer) is the gate dielectric, the 2D-transition metal dichalcogenide layer 302 is the work function metal layer, and the metallic capping layer 402 is the gate electrode layer. In some embodiments, a total gate stack thickness is about 20 nanometers or less, such as less than 10 nanometers or less than 7 nm. For example, the thickness of the gate stack may be about 20 nm, about 15 nm, about 10 nm, about 8 nm or about 5 nm. Similar gate stack thicknesses are applicable to both NMOS and PMOS devices.

In accordance with examples of the disclosure, structure 400 (FIG. 4) can include at least a portion of a partially fabricated semiconductor device structure. In such cases, the structure 400 can comprises a portion of a CMOS device. In such examples, structure 400 can comprise a portion of an NMOS device structure and the 2D-transition metal dichalcogenide layer 302 functions as a stable metallic n-type work function metal selected from a group consisting of MoS₂, MoTe₂, VS₂, wherein the gate stack 404 has an effective work function between 4.2 eV and 4.4 eV. In alternative examples, structure 400 can comprise a portion of a PMOS device structure and the 2D-transition metal dichalcogenide layer 302 functions as a stable metallic p-type work function metal selected from a group consisting of TaS₂, TaSe₂, NbSe₂, TiSe₂, and VSe₂, wherein the gate stack 404 has an effective work function between 5.2 eV and 5.6 eV.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

Although certain embodiments and examples have been discussed, it will be understood by those skilled in the art that the scope of the claims extend beyond the specifically disclosed embodiments to other alternative embodiments and/or uses and obvious modifications and equivalents thereof. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation.

1. A method of forming a semiconductor structure, the method comprising:
seating a substrate within a reaction chamber, the substrate including a dielectric layer;
depositing a 2D-transition metal dichalcogenide layer directly on the dielectric layer by performing one or more cycles of a cyclical deposition process, each deposition cycle of the cyclical deposition process comprising;
providing a transition metal precursor to the reaction chamber;
providing a chalcogen precursor to the reaction chamber; and
depositing a metallic capping layer directly on the 2D-transition metal dichalcogenide layer.

2. The method of claim 1, wherein the dielectric layer comprises a high-k dielectric layer.

3. The method of claim 2, wherein the cyclical deposition process comprises an atomic layer deposition process.

4. The method of claim 3, wherein the substrate temperature during the atomic layer deposition process is less than 500° C.

5. The method of claim 1, wherein the 2D-transition metal dichalcogenide layer comprises a metallic work function layer.

6. The method of claim 5, wherein the 2D-transition metal dichalcogenide layer is selected from a group consisting of MoS₂, VS₂, TaS₂, MoTe₂, TaSe₂, NbSe₂, and TiSe₂.

7. The method of claim 1, wherein the transition metal precursor comprises a transition metal element selected from a group consisting of molybdenum, vanadium, tantalum, niobium, and titanium.

8. The method of claim 1, wherein the chalcogen precursor comprises a chalcogen element selected from a group consisting of sulphur, selenium, and tellurium.

9. The method of claim 1, wherein one or more of the deposition cycles further comprises providing a metal precursor to the reaction chamber.

10. The method of claim 9, wherein the metal precursor comprises an additional metal element and the transition metal precursor comprises a transition metal element which is different from the additional metal element.

11. The method of claim 10, wherein the additional metal element is selected from a group consisting of aluminum, tungsten, and tellurium.

12. The method of claim 11, wherein the additional metal element comprises a dopant metal element and the 2D-transition metal dichalcogenide layer comprises a metal doped 2D-transtion metal dichalcogenide layer.

13. The method of claim 11, wherein the additional metal element comprises a metal alloying element and the 2D-transition metal dichalcogenide layer comprise a ternary phase 2D-transtion metal dichalcogenide alloy layer.

14. The method of claim 1, wherein the 2D-transition metal dichalcogenide layer is deposited to a thickness of between 1 nanometer and 5 nanometers.

15. The method of claim 1, wherein the 2D-transition metal dichalcogenide layer is deposited to a thickness between 1 monolayer and 5 monolayers.

16. A method of forming at least a portion of a gate stack for a semiconductor device structure, the method comprising:
seating a substrate within a reaction chamber, the substrate comprising a plurality of partially fabricated device structures, wherein one or more of the partially fabricated device structures includes a surface layer comprising a high-k dielectric layer;
performing one of or more deposition cycles of a first atomic layer deposition process to deposit a metallic 2D-transition metal dichalcogenide work function layer directly on a surface of the high-k dielectric layer; and
performing one or more deposition cycles of a second atomic layer deposition process to deposit a metallic capping layer directly on the metallic 2D-transition metal dichalcogenide layer.

17. The method of claim 16, wherein the high-k dielectric layer, the metallic 2D-transition metal dichalcogenide work function layer, and the metallic capping layer together comprise a gate stack to the semiconductor device structure.

18. The method of claim 17, wherein the semiconductor device structure comprises a NMOS device structure and the effective work function of the gate stack is between 4.2 eV and 4.4 eV with a total gate stack thickness of less than 20 nanometers.

19. The method of claim 17, wherein semiconductor device structure comprises a PMOS device structure and the effective work function of the gate stack is between 5.2 eV and 5.6 eV with a total gate stack thickness of less than 20 nanometers.

20. A method for forming a ternary phase 2D-transition metal dichalcogenide layer by an atomic layer deposition process (ALD), the ternary phase 2D-transition metal dichalcogenide layer having a chemical formula containing a transition metal element, a chalcogen element, and a ternary element consisting of a metal element different to the transition metal element, wherein a transition metal containing precursor is used as a source for the transition metal element, a chalcogen containing precursor is used as the source of the chalcogen element, and a metal containing precursor is used as the source of the ternary metal element.
